(19) United States
(12) Patent Application Publication
(10) Pub. No.: US 2008/0042200 A1
(43) Pub. Date: Feb. 21, 2008

(54) THIN-FILM TRANSISTOR AND FABRICATION METHOD THEREOF

(75) Inventors: Jhih-Ping Lu, Yi-Lan City (TW); Yuh-Zheng Lee, Hsinchu City (TW); Je-Ping Hu, Taipei Hsien (TW); Hsuan Ming Tsai, Tainan Hsien (TW); Chao-Kai Cheng, Miaoli County (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/759,169

(22) Filed: Jun. 6, 2007

(30) Foreign Application Priority Data
Aug. 18, 2006 (TW) TW95130395

(51) Int. Cl. H01L 29/786; H01L 21/336

(52) U.S. Cl. 257/347; 438/164; 257/E21.411; 257/E29.273

(57) ABSTRACT

A thin-film transistor and method for fabricating a thin-film transistor is disclosed. In the method, a controlled micro-line is formed by inkjet printing in combination with the coffee ring effect. The micro-line may be a semiconductor or an insulator. A high-current thin-film transistor utilizing the micro-line of the coffee ring as a channel is formed. A high current TFT can be achieved by utilizing the micro-line structure of the coffee ring ridge as a TFT channel.

### BACKGROUND OF THE INVENTION

1. Field of the Invention

The invention relates to a thin-film transistor, and more particularly to a thin-film transistor formed by inkjet printing in combination with the coffee ring effect.

2. Description of the Related Art

Recently, organic material has been put to use in electronic device fabrication. A variety of photoelectric devices can be formed from combinations of organic electronic materials. Examples of photoelectric devices comprising organic electronic material included resistors, passive element capacitors, thin-film transistors, active element memory, displays, monitors, solar batteries, and others.

Small electronic devices require small elements to achieve high resolution. Thin-film transistors (TFT) used in inorganic semiconductors among others, have been reduced to the 60 nm scale. Although 60 nm scale technology is applicable to general displays and electronic devices, organic material and soluble semiconductor materials show better potential for mass production of electronic devices due to the simpler process and lower cost thereof. Organic material is also more suitable than inorganic material for fabrication on flexible substrates. Conventional film forming technologies comprise vacuum deposition, spin-coating, or screen printing. These technologies, however, are unable to extend the length of a gate (i.e. TFT channel resolution) to several micrometers and less. A high-current TFT is formed by reducing the length and increasing the width of a gate, thus, gates with a shorter length and a wider width are desirable.

Organic polymer material is stable and soluble, thus, a solution of polymer material can be used to make a product by a dispensing method. An inkjet printing dispensing method is more suitable for mass production.

Micrometer scale droplet can be formed on a substrate by inkjet printing of a pico-sized droplet, thus, a micrometer sized electronic device can be fabricated. In general, the diameter of the drop on the substrate is from several tens to several hundreds of micrometers, and is thus too large for high resolution electronic devices.

A mechanism for forming coffee rings is shown in FIG. 1A to FIG. 1C. The mechanism can be referenced in Nature, Vol. 389, 1997, Robert D. Deegan, Olgica Bakajin et al., “Capillary Flow as the Cause of Ring Stains from Dried Liquid props”. In this article, the natural phenomenon of a solution containing a solid solute drying into a coffee ring is illustrated. An ink drop 12 is formed on a substrate 10, a perimeter of the drop is rapidly dried to form a contact line 14. Here we ascribe the characteristic pattern of the coffee ring to a form of capillary flow in which pinning of the contact line of the drying drop ensures that liquid evaporating from the edge is replenished by liquid from the interior. The phenomenon is due to a geometrical constraint: the free surface, constrained by a pinned contact line, squeezes the fluid outward to compensate for evaporative losses. The coffee ring remains as long as (1) the solvent meets the surface of the substrate at a non-zero contact angle, (2) the contact line 14 is formed on the substrate 10 from the drop 12 (i.e., the drop 12 containing a solute 16), (3) the solvent evaporates. In addition, the mechanisms are typically responsible for solute transport, thus, surface tension gradients, solute diffusion, electrostatic and gravitational effects are negligible in coffee ring formation.

Direct writing technology is widely used for circuit element fabrication. For example, Xennia and Carclo have used inkjet printing to form a conductive metal wire with a width of about 50 μm on a plastic or paper substrate. An organic TFT can be fabricated by inkjet printing, but the gate line of TFT is still fabricated by photolithography to form a width of 5 μm. In “Using convective flow splitting for the direct printing of fine copper lines” Appl. Phys. Vol. 77, No. 13, p. 2063, Tanja et al. of Princeton College used a phenomenon of convective flow splitting to form a Cu conductive wire. The width of the formed 500 μm Cu conductive wire was reduced, by dispensing, and then vaporizing solvent to form a wire with a width of 100 μm. The Cu wire can be fabricated by inkjet printing to achieve an initial width of 80 μm, and then by vaporizing solvent, reduced to a width of 10 μm. Although the width of the wire is reduced by the coffee ring effect, there is still a solute in the central part of the coffee ring. Because there are no isolated lines formed by the described technology, it cannot be used for fabricating an electronic device.

U.S. Pat. No. 6,838,361 discloses a TFT fabrication method. In this method, after source/drain electrodes are formed, the coffee ring is removed by a lift-off process. The disadvantages of this method include an additional cost for lift-off process. At the same time, lift-off processes damaged the surfaces of the source/drain electrodes.

The invention employs an inkjet printing and an etching process disclosed in Taiwan Patent No. 1224361 to form and reduce the width of an isolated line. The character of the fine line is further used in the invention to form a TFT.

### BRIEF SUMMARY OF THE INVENTION

One object of the invention is to use an inkjet printing in combination with the coffee ring effect to form a micro-line. The micro-line may be a semiconductor or an insulator. A high-current thin-film transistor is formed with the micro-line of the coffee ring as a channel with a length of several micrometers below.

Another object of the invention is to provide a TFT, wherein the central part of the coffee ring film is removed by etching to form an isolated line and reduce the width of the line by a controlled etching rate. In addition, the invention further dispenses an active material having solubility of solution on the micro-line structure of the coffee ring ridge. The active material can slightly etch the coffee ring ridge into a gradient concentration of the ridge.

To achieve the described and other objects, the invention provides a thin-film transistor (TFT). The TFT comprises a separating layer disposed over a substrate, wherein the separating layer is a ridge of a coffee ring. A source/drain layer is disposed on opposite sides of the ridge. An active layer is disposed on the separating layer and the source/drain layer. A gate dielectric layer and a gate layer are disposed over the substrate, thus, fabrication of a TFT is complete.

The invention further provides a thin-film transistor, comprising a separating layer disposed over a substrate, wherein the separating layer is a coffee ring ridge. The coffee ring ridge is formed from an active material. A source/drain layer is disposed on opposite sides of the ridge. A gate dielectric layer and a gate layer are disposed over the substrate, thus, fabrication of a TFT is complete.

The invention further provides a method for fabricating a thin-film transistor, comprising inkjet printing a separating layer over a substrate to form a coffee ring. A central part of the coffee ring is then removed by etching leaving a ridge of the coffee ring. A source/drain layer is formed on opposite sides of the ridge by inkjet printing. An active layer is then disposed on the ridge and the source/drain layer by inkjet printing or coating. A gate dielectric layer and a gate layer are then formed over the substrate by inkjet printing or coating to complete fabrication of a TFT.

The invention further provides another method for fabricating a thin-film transistor, comprising inkjet printing a separating layer over a substrate to form a coffee ring. The coffee ring is formed from an active material. A central part of the coffee ring is then removed by etching leaving a ridge of the coffee ring. A source/drain layer is formed on opposite sides of the ridge by inkjet printing. A gate dielectric layer and a gate layer are then formed over the substrate by inkjet printing or coating to complete fabrication of a TFT.

A detailed description is given in the following embodiments with reference to the accompanying drawings.

### BRIEF DESCRIPTION OF THE DRAWINGS

The invention can be more fully understood by reading the subsequent detailed description and examples with reference to the accompanying drawings, wherein:

FIG. 1A-1C show schematic cross sections of a mechanism for forming coffee rings;

FIG. 2A-2F show schematic cross sections of processes for forming an upper-gate TFT of a first embodiment of the invention;

FIG. 3 shows a schematic cross section of an upper-gate TFT of a second embodiment of the invention;

FIG. 4 shows a schematic cross section of a lower-gate TFT of a third embodiment of the invention; and

FIG. 5 shows a schematic cross section of a lower-gate TFT of a fourth embodiment of the invention.

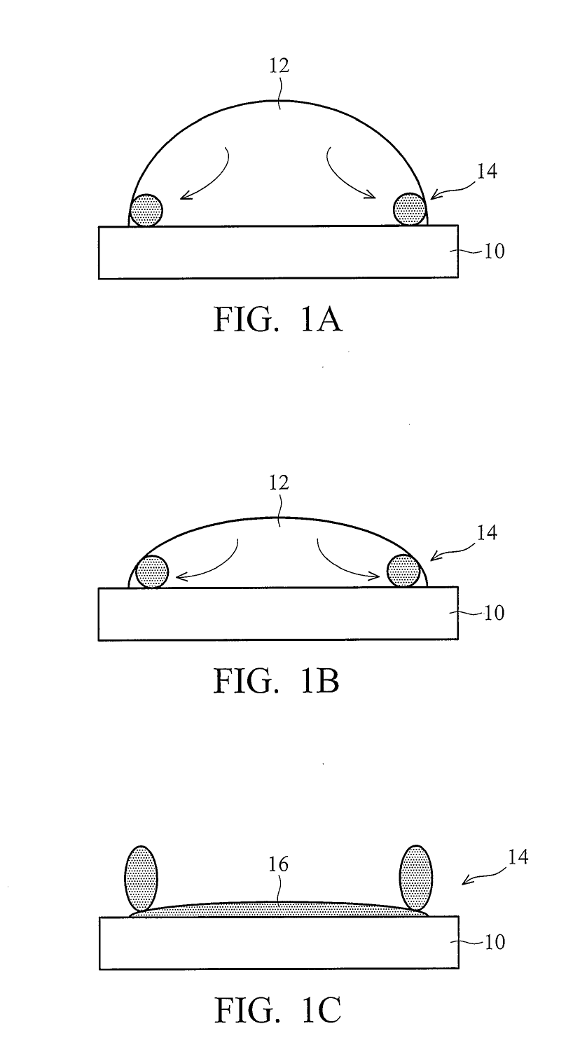

### DETAILED DESCRIPTION OF THE INVENTION

The following description is of the best-contemplated mode of carrying out the invention. The description is provided for illustrating the general principles of the invention and is not meant to be limiting. The scope of the invention is best determined by reference to the appended claims.

The invention utilizes an inkjet printing micro-drop and the natural phenomenon of a solution drop drying into a coffee ring to make a micro-line structure of the coffee ring ridge. The thin central part of the coffee ring is removed by surface micro-etching to reduce the size of the micro-line structure of the coffee ring ridge to below the micrometer scale. Use the micro-line as an insulator or a semiconductor can yield a thin-film transistor (TFT).

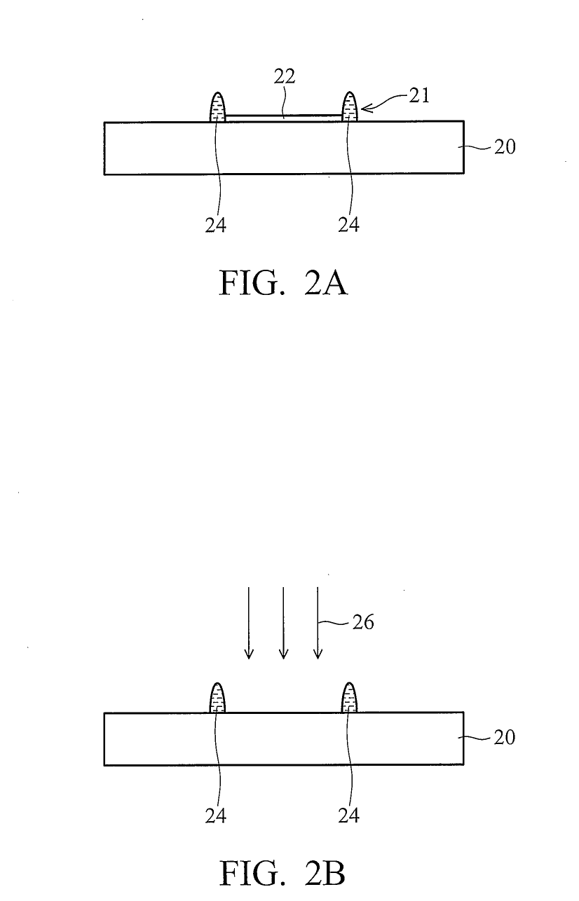

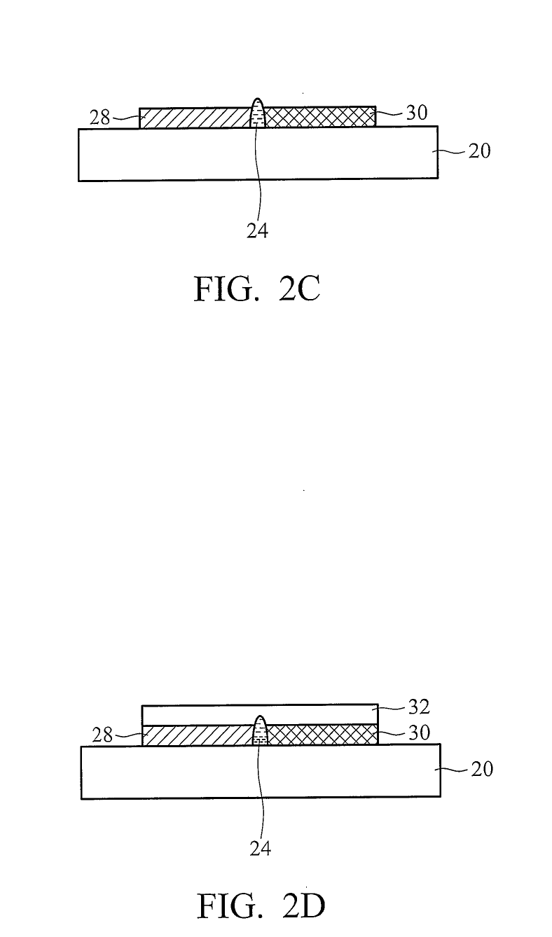

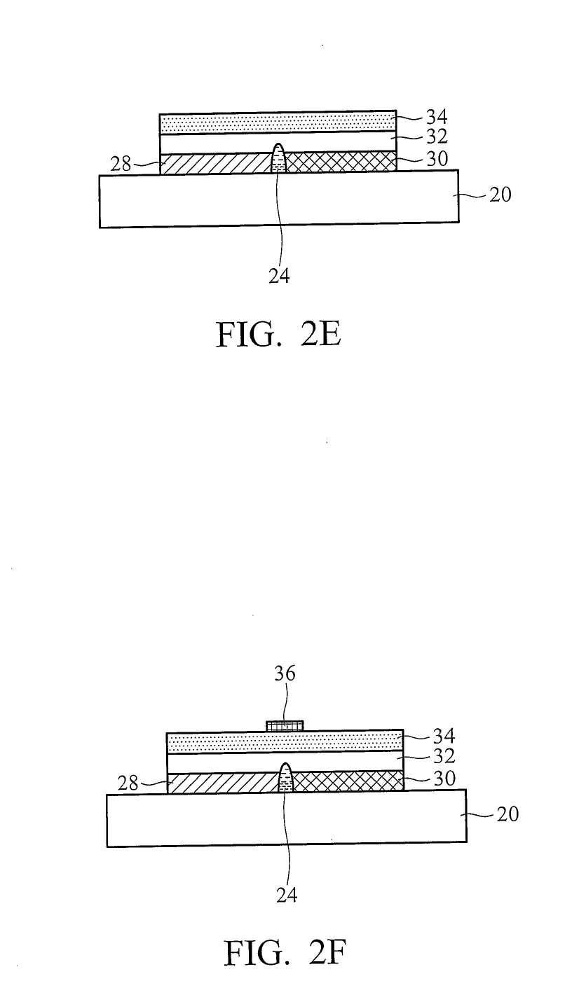

The cross sections of fabrication steps of the first embodiment of the invention are shown in FIGS. 2A-2F. Referring to FIG. 2A, a substrate 20, such as glass or plastic substrate, is first provided. A semiconductor material solution is inkjet printed by a sprinkle-nozzle on the substrate 20 into a dot or a line shape, and then dried into a coffee ring film 21. The semiconductor material may be, but is not limited to, poly-(3-hexylthiophene) (P3HT) or poly-9(9dioctylfluorene-co-bithiophene) (F8T2). The semiconductor material is dissolved in a solvent into a solution for inkjet printing. The solvent includes watery liquid or an oily liquid such as xylene.

Referring to FIG. 2B, a central part 22 of the coffee ring film 21 is removed by a surface micro-etching method, and a coffee ring ridge 24 is left as a separating layer 24. If the semiconductor material solution is inkjet printed on the substrate 20 into the shape of a line, two parallel micrometer scale lines are formed on the substrate. The width of the coffee ring ridge line is below about 50 μm, and the height of the coffee ring ridge line is below about 10 μm. As shown in FIG. 2B, the coffee ring ridge 24 is treated with plasma 26 to make the coffee ring ridge 24 hydrophobic. The utilized plasma gas may be O₂, N₂, CF₄, SF₆ or combinations thereof. The surface micro-etching can be practiced by plasma, immersion, spraying, dispensing, printing or combinations thereof. The spraying, dispensing or printing is practiced by sprinkling a solvent on the substrate to etch the thin central part of the coffee ring.

Then referring to FIG. 2C, a solution of conductive material is inkjet printed on the coffee ring ridge into two separate areas due to the hydrophobic coffee ring ridge. The two separate areas are formed into films on the two sides of the ridge as a source layer 28 and a drain layer 30. The conductive material may be poly-3,4-ethylenedioxythiophene (PEDOT).

Referring to FIG. 2D, an active layer 32 is inkjet printed or coated on the coffee ring ridge 24, the source layer 28 and the drain layer 30. The active layer is formed from a solution of semiconductor material which can be inkjet printed, such as P3HT or F8T2 dissolved in a solvent. In the first embodiment of the invention, the active layer material solution can dissolve and micro-etch the separating layer 24 into a layer of graded concentration for enhancing TFT performance. As shown in FIG. 2D, the concentration of a part of the separating layer 24 near the active layer 32 is lower.

Referring to FIG. 2E, an upper gate dielectric layer 34 is inkjet printed or coated on the active layer 32. The upper gate dielectric layer can be formed of an insulating material, such as polymethyl methacrylate (PMMA), polyvinyl alcohol (PVA), or photoacrylate.

Referring to FIG. 2F, an upper gate layer 36 is finally inkjet printed or coated on the upper gate dielectric layer 34 and aligned with the separating layer 24 to form a TFT. The upper gate layer can be formed of a solution of conductive material such as PEDOT.

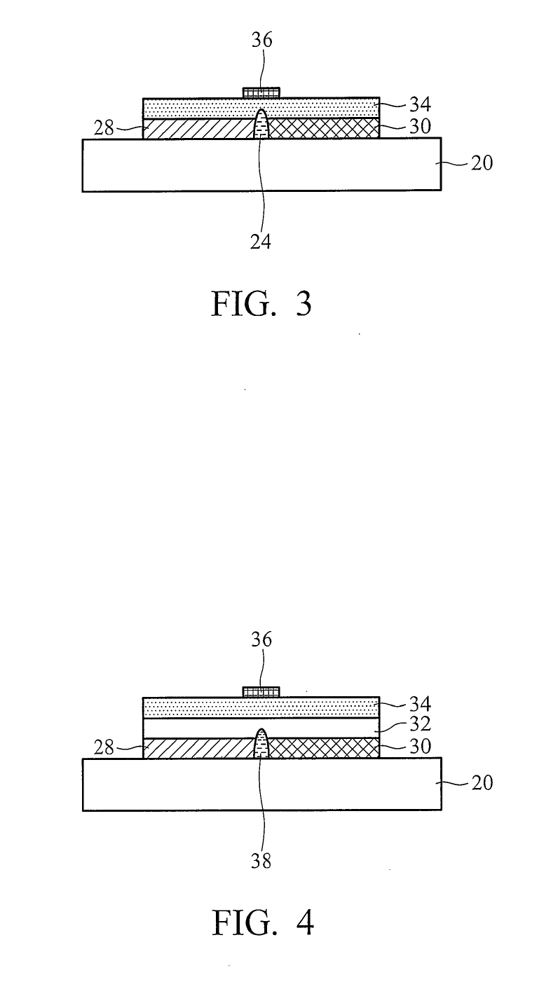

In the second embodiment of the invention the active layer 32 of the first embodiment is removed. As shown in FIG. 3, the coffee ring ridge (i.e., separating layer) 24 is formed on the substrate 20. The source layer 28 and the drain layer 30 are disposed on opposite sides of the ridge. The gate dielectric layer 34 is disposed on the source layer, the drain layer and the ridge. The gate layer 36 is then disposed on the gate dielectric layer. The material and fabrication method of the layers of the second embodiment of the invention are the same as the first embodiment. The coffee ring ridge is formed from an active material.

In the third embodiment of the invention a separating layer 38 thereof is formed of a solution of insulating material, such as PMMA, PVA or photoacryle dissolved in a solvent to form a solution for inkjet printing. The solvent may be a watery liquid or an oily liquid such as xylene. As shown in FIG. 4, the coffee ring ridge (i.e., separating layer) 38 is formed on the substrate 20. The source layer 28 and the drain layer 30 are disposed on opposite sides of the ridge. The active layer 32 is disposed on the source layer, the drain layer and the ridge. The gate dielectric layer 34 is disposed on the active layer and the gate layer 36 is disposed on the gate dielectric layer. The material and fabrication method of the layers of the third embodiment of the invention are the same as the first embodiment.

In the same way, a solution of material of the active layer 32 can dissolve and micro-etch the separating layer 38 into a layer of graded concentration for enhancing TFT performance. As shown in FIG. 4, the concentration of a part of the separating layer 38 near the active layer 32 is higher.

According to the first embodiment of the invention, the substrate can be replaced by a substrate having a conductive layer and a gate dielectric layer, and the upper gate layer and the upper gate dielectric layer can be removed to form a TFT with bottom gate structure. The structures of the second and third embodiments can be changed into a bottom gate TFT by following the described methods. For example, the fourth embodiment is a bottom gate TFT formed according to change the substrate of the first embodiment.

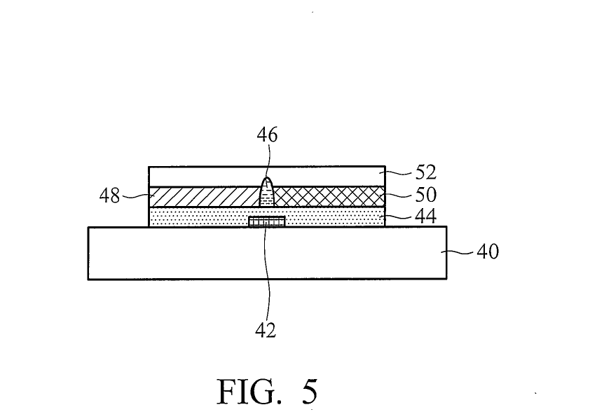

As shown in FIG. 5, a bottom gate layer 42 is disposed on a substrate 40. The bottom gate layer can be formed of PEDOT. A bottom gate dielectric layer 44 is disposed on the bottom gate layer and the substrate, which can be formed of an insulating material. In one embodiment, the bottom gate dielectric layer is formed of an inorganic insulating material such as SiO2 or Si3N4 etc.

There are several layers over the bottom gate dielectric layer forming a bottom gate TFT according to the material and fabrication method of the first embodiment. A separating layer 46 is disposed on the bottom gate dielectric layer. A source layer 48 and a drain layer 50 are disposed on opposite sides of the separating layer. An active layer 52 is then disposed on the source layer, the drain layer and the separating layer to obtain the bottom gate TFT. In the bottom gate TFT of the fourth embodiment of the invention, the separating layer is also a layer of graded concentration.

In one embodiment, the material of separating layer 46 may be the same as that of the third embodiment, wherein a solution of insulating material, such as PMMA, PVA or photoacrylate is dissolved in a solvent to form a solution for inkjet printing. The solvent may be a watery or oily liquid such as xylene. In the described bottom gate TFT, the separating layer is also a layer of graded concentration.

According to the invention, a micro-length of gate is formed by inkjet printing in combination with the coffee ring effect, and this has no need to be formed by photolithography. Use the micro-length of gate to achieve a reduced channel length of a TFT can get a high-current of the TFT.

Embodiments of the invention provide the following advantages. The micro-line of the coffee ring formed by inkjet printing can serve as a channel, source/drain, or gate of a TFT, wherein the micro-line can be formed of insulating, semiconductor, or conductive materials. TFTs with a circular or linear shape can also be provided. The channel of TFTs formed by inkjet printing can be dissolved by a solution of a subsequent process to improve the interfacial quality between source and drain, without requiring a lift-off process.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A thin-film transistor, comprising:
a substrate;
a separating layer disposed over the substrate, wherein the separating layer is a ridge of a coffee ring;
a source/drain layer disposed on opposite sides of the ridge;
an active layer disposed on the separating layer and the source/drain layer; and
a gate dielectric layer and a gate layer disposed over the substrate.

2. The thin-film transistor as claimed in claim 1, wherein the separating layer is formed of a material comprising semiconductor or insulator material or a combination thereof.

3. The thin-film transistor as claimed in claim 1, wherein the active layer is formed of a semiconductor material.

4. The thin-film transistor as claimed in claim 1, wherein the separating layer and the active layer are formed of the same material.

5. The thin-film transistor as claimed in claim 1, wherein the separating layer and the active layer are formed of different materials.

6. The thin-film transistor as claimed in claim 1, wherein the separating layer is a gradient layer.

7. The thin-film transistor as claimed in claim 1, wherein the gate dielectric layer is disposed on the active layer.

8. The thin-film transistor as claimed in claim 7, wherein the gate layer is disposed on the gate dielectric layer and above the ridge.

9. The thin-film transistor as claimed in claim 1, wherein the gate layer is disposed on the substrate and under the separating layer and the source/drain layer.

10. The thin-film transistor as claimed in claim 9, wherein the gate dielectric layer is disposed between the gate layer, the separating layer and the source/drain layer.

11. The thin-film transistor as claimed in claim 1, wherein the source/drain layer is a conductive layer formed from a solution of conductive material.

12. The thin-film transistor as claimed in claim 1, wherein the gate dielectric layer is made of an insulating material.

13. The thin-film transistor as claimed in claim 1, wherein the gate layer is a conductive layer formed from a solution of conductive material.

14. A thin-film transistor, comprising:
a substrate;
a separating layer disposed over the substrate, wherein the separating layer is a ridge of a coffee ring;
a source/drain layer disposed on opposite sides of the ridge; and
a gate dielectric layer and a gate layer disposed over the substrate.

15. The thin-film transistor as claimed in claim 14, wherein the separating layer is formed of a semiconductor material.

16. The thin-film transistor as claimed in claim 14, wherein the gate dielectric layer is disposed on the separating layer and the source/drain layer, and the gate layer is disposed on the gate dielectric layer and above the ridge.

17. The thin-film transistor as claimed in claim 14, wherein the gate layer is disposed on the substrate, and the gate dielectric layer is disposed between the gate layer, the separating layer and the source/drain layer.

18. The thin-film transistor as claimed in claim 14, wherein the gate layer and the source/drain layer are conductive layers formed from a solution of conductive material.

19. The thin-film transistor as claimed in claim 14, wherein the gate dielectric layer is made of an insulating material.

20. A method of fabricating a thin-film transistor, comprising:
providing a substrate;
inkjet printing a separating layer over the substrate to form a coffee ring;
etching to remove a central part of the coffee ring, leaving a ridge of the coffee ring;
inkjet printing a source/drain layer on opposite sides of the ridge;
inkjet printing or coating an active layer disposed on the ridge and the source/drain layer; and
inkjet printing or coating a gate dielectric layer and a gate layer over the substrate to complete a thin-film transistor.

21. The method as claimed in claim 20, further comprising treating the ridge with a plasma to make the ridge hydrophobic.

22. The method as claimed in claim 21, wherein the plasma comprises O₂, N₂, CF₄, SF₆ or combinations thereof.

23. The method as claimed in claim 20, wherein the gate dielectric layer is disposed on the active layer.

24. The method as claimed in claim 23, wherein the gate layer is disposed on the gate dielectric layer and above the ridge.

25. The method as claimed in claim 20, wherein the gate layer is disposed on the substrate and under the separating layer and the source/drain layer.

26. The method as claimed in claim 25, wherein the gate dielectric layer is disposed between the gate layer, the separating layer and the source/drain layer.

27. The method as claimed in claim 20, wherein the separating layer is formed of a material comprising a solution of semiconductor material, a solution of insulating material or combinations thereof.

28. The method as claimed in claim 20, wherein the active layer is formed of a semiconductor material.

29. The method as claimed in claim 20, wherein the separating layer and the active layer are formed of the same material.

30. The method as claimed in claim 20, wherein the separating layer and the active layer are formed of different materials.

31. The method as claimed in claim 20, wherein the active layer slightly etches the ridge into a gradual change of the separating layer.

32. The method as claimed in claim 20, wherein the source/drain layer is formed from a solution of conductive material.

33. The method as claimed in claim 20, wherein the gate dielectric layer is made of an insulating material.

34. The method as claimed in claim 20, wherein the gate layer is made of a solution of conductive material.

35. The method as claimed in claim 20, wherein the etching is surface micro-etching.

36. The method as claimed in claim 35, wherein the surface micro-etching is performed by plasma, dipping, spraying, dispensing or printing.

37. A method of fabricating a thin-film transistor, comprising:
providing a substrate;
inkjet printing a separating layer over the substrate to form a coffee ring;
etching to remove a central part of the coffee ring, leaving a ridge of the coffee ring;
inkjet printing a source/drain layer on opposite sides of the ridge; and
inkjet printing or coating a gate dielectric layer and a gate layer over the substrate.

38. The method as claimed in claim 37, further comprising treating the ridge with a plasma to make the ridge hydrophobic.

39. The method as claimed in claim 37, wherein the separating layer is formed of a solution of semiconductor material.

40. The method as claimed in claim 37, wherein the gate dielectric layer is disposed on the separating layer and the source/drain layer, and the gate layer is disposed on the gate dielectric layer and above the ridge.

41. The method as claimed in claim 37, wherein the gate layer is disposed on the substrate, and the gate dielectric layer is disposed between the gate layer, the separating layer and the source/drain layer.

42. The method as claimed in claim 37, wherein the gate layer and the source/drain layer are formed of a solution of conductive material.

43. The method as claimed in claim 37, wherein the gate dielectric layer is formed of an insulating material.
